(19) United States
(12) Patent Application Publication
(10) Pub. No.: US 2024/0218294 A1
(43) Pub. Date: Jul. 4, 2024

(54) CLEANING COMPOSITION, CLEANING METHOD, AND MANUFACTURING METHOD OF SEMICONDUCTOR

(71) Applicant: Daxin materials corporation, Taichung City (TW)

(72) Inventors: Hui-yi TANG, Taichung City (TW); Tzu-chi WANG, Taichung City (TW); Yi-cheng CHEN, Taichung City (TW)

(73) Assignee: Daxin materials corporation, Taichung City (TW)

(21) Appl. No.: 18/502,116

(22) Filed: Nov. 6, 2023

(30) Foreign Application Priority Data
Dec. 30, 2022 (TW) 111150995

(51) Int. Cl. C11D 3/30; C11D 3/43; C11D 11/00; H01L 21/02

(52) U.S. Cl. CPC C11D 3/30; C11D 3/43; C11D 11/0047; H01L 21/0206

(57) ABSTRACT

A cleaning composition for electronics industries is provided. The cleaning composition includes 40% to 90% by weight of an amine solvent having a structure of following formula (1), a quaternary ammonium salt, and water. Wherein, R1, R2, R4, and R5 are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R3 is a linear alkylene group having 1 to 5 carbon atoms or a branched alkylene group having 3 to 5 carbon atoms.

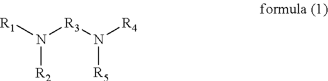

### CROSS REFERENCE TO RELATED APPLICATIONS

This application claims the benefit of priority of Taiwan Patent Application No. 111150995, filed on Dec. 30, 2022, the contents of which are incorporated by reference as if fully set forth herein in their entirety.

### FIELD OF INVENTION

The present disclosure relates to a cleaning composition for electronics industries, and more particularly, to a cleaning composition for semiconductor manufacturing processes, a cleaning method using the cleaning composition, and a manufacturing method of semiconductor.

### BACKGROUND OF INVENTION

Semiconductor devices are usually formed by stacking functional layers such as metal wiring layers, dielectric layers, insulating layers, and anti-reflective layers on semiconductor substrates which are composed of silicon wafers. Resist patterns formed by photolithography processes are used as masks for etching, and above-mentioned layers are processed to form above-mentioned laminated layers. The resist patterns in the photolithography processes mentioned above are formed by using film layers such as resist films, anti-reflective films, or sacrificial films.

Residues generated from the metal wiring layers or the dielectric layers in etching steps are removed by cleaning liquid, thereby preventing subsequent processes from being adversely affected, and reducing problems of yields of the semiconductor devices caused by the residues. In general, coating films that can be removed by the cleaning liquid are, for example, the resist films corresponding to various exposure wavelengths such as g-line, i-line, KrF excimer laser, ArF excimer laser, EUV, etc., the anti-reflective films disposed under the resist films, the sacrificial films composed of inorganic films such as silicon masks that contain silicon atoms, or protective films disposed on the resist films. Specifically, in liquid immersion lithography, resist underlayers, the resist films, and the protective films are stacked on substrates in sequence, so developing a cleaning liquid that can be used to clean and effectively remove various film layers that are used as masks without affecting yields of the subsequent processes has always been a direction of continuous efforts for industries.

### SUMMARY OF INVENTION

An objective of the present disclosure is to provide a cleaning composition to effectively clean and remove residues of resists, siloxane resin film layers, or other film layers on substrates or semiconductor substrates. Dimethyl sulfoxide is generally used as a main solvent in commercially available semiconductor cleaning agents due to its good solubility for organic and inorganic substances. Wastewater generated during the manufacturing processes has a certain amount residue of dimethyl sulfoxide. If the wastewater is not properly treated, it will be decomposed and reduced to form dimethyl sulfide that has a low olfactory threshold and a foul smell. The air pollution produced will have a great impact on the people in industrial areas and surrounding residential areas. The cleaning composition can effectively remove the residues of resists, siloxane resin film layers, or other film layers under the premise of taking environmental protection into consideration.

In an embodiment of the present disclosure, the cleaning composition includes 40% to 90% by weight of an amine solvent having a structure of following formula (1), a quaternary ammonium salt, and water;

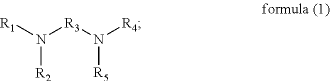

wherein, R₁, R₂, R₄, and R₅ are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R₃ is a linear alkylene group having 1 to 5 carbon atoms or a branched alkylene group having 3 to 5 carbon atoms.

Another objective of the present disclosure is to provide a cleaning method. The cleaning method includes a step of using the cleaning composition mentioned above to clean and remove a residue or a residual film attached onto a device component, wherein, the residue or the residual film includes a resist or a siloxane resin film layer.

Yet another objective of the present disclosure is to provide a manufacturing method of a semiconductor. The manufacturing method of the semiconductor includes following steps:
providing a substrate;
coating a siloxane resin layer on the substrate;
coating a photoresist layer on the siloxane resin layer to form a multilayered substrate;
performing photolithography and etching processes on the multilayered substrate; and

using the cleaning composition mentioned above to clean and remove residues of the siloxane resin layer and the photoresist layer attached onto the substrate.

### DETAILED DESCRIPTION OF PREFERRED EMBODIMENTS

Before describing at least one embodiment of the present disclosure in detail, it should be understood that the present disclosure is not necessarily limited to its application in the details illustrated in the following examples, for example, the number of embodiments, specific mixing ratio used thereof, etc. The present disclosure can be implemented or realized in other embodiments or in various ways.

### [Cleaning Composition]

The present disclosure provides a cleaning composition for electronics industries. The cleaning composition includes 40% to 90% by weight of an amine solvent having a structure of following formula (1), a quaternary ammonium salt, and water;

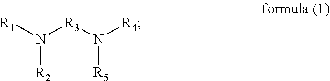

wherein, R₁, R₂, R₄, and R₅ are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R₃ is a linear alkylene group having 1 to 5 carbon atoms or a branched alkylene group having 3 to 5 carbon atoms.

The cleaning composition can be used to clean and remove residues of resists, siloxane resin film layers, or other film layers on substrates or semiconductor substrates. The cleaning composition can effectively remove the residues of resists, siloxane resin film layers, or other film layers under the premise of taking environmental protection into consideration. Each component will be described in detail in the following.

### [Amine Solvent]

In an embodiment of the present disclosure, preferably, R₁ and R₂ are each independently hydrogen or the linear alkyl group having 1 to 4 carbon atoms; R₄ and R₅ are each independently hydrogen, a linear alkyl group having 1 to 2 carbon atoms, or a linear alkylamine having 1 to 2 carbon atoms; and R₃ is the linear alkylene group having 1 to 5 carbon atoms or the branched alkylene group having 3 to 5 carbon atoms.

More preferably, in an embodiment of the present disclosure, R₁ and R₂ are each independently hydrogen or a linear alkyl group having 1 to 3 carbon atoms; R₄ and R₅ are each independently hydrogen; and R₃ is a linear alkylene group having 1 to 4 carbon atoms or the branched alkylene group having 3 to 5 carbon atoms.

Specifically, in an embodiment of the present disclosure, the amine solvent includes at least one of N,N-dimethyl-1,3-diaminopropane, N,N-diethyl-1,3-diaminopropane, ethylenediamine, 1,3-diaminopropane, diethylenetriamine, 1,2-propanediamine, N,N,N′,N′-tetramethyl-1,3-propanediamine, 3,3′-diaminodipropylamine, 2,2-dimethyl-1,3-propanediamine, 1,4-diaminobutane, 1,3-diaminobutane, 2,3-diaminobutane, 1,5-diaminopentane, 2,4-diaminopentane, N-isopropylethylenediamine, N,N′-diisopropylethylenediamine, or N1-isopropyldiethylenetriamine.

Preferably, the amine solvent includes at least one of N,N-dimethyl-1,3-diaminopropane, N,N-diethyl-1,3-diaminopropane, ethylenediamine, or 1,3-diaminopropane.

Specifically, an amount of the amine solvent in the cleaning composition ranges from 40% to 90% by weight. Preferably, the amount of the amine solvent in the cleaning composition ranges from 65% to 90% by weight. If the amine solvent accounts for less than 40% by weight of the cleaning composition, it is not beneficial for dissolving hydrolysis products of bottom anti-reflective coatings (BARCs).

### [Quaternary Ammonium Salt]

In an embodiment of the present disclosure, the quaternary ammonium salt is quaternary ammonium hydroxide having a structure shown in a following formula (2):

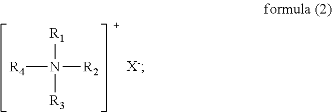

wherein, R₁ to R₄ are each independently an alkyl group having 1 to 4 carbon atoms that is unsubstituted or substituted with a hydroxyl group, and X is OH.

Specifically, in an embodiment of the present disclosure, the quaternary ammonium salt may include at least one of tetramethylammonium hydroxide (TMAH), tetraethylammonium hydroxide (TEAH), tetrapropylammonium hydroxide, tetrabutylammonium hydroxide, ethyltrimethylammonium hydroxide, diethyldimethylammonium hydroxide, (2-hydroxyethyl)trimethylammonium hydroxide, bis(2-hydroxide, or tris(2-hydroxyethyl)dimethylammonium hydroxyethyl)methylammonium hydroxide. In an embodiment of the present disclosure, the quaternary ammonium salt is preferably tetramethylammonium hydroxide (TMAH) or tetraethylammonium hydroxide (TEAH).

Specifically, an amount of the quaternary ammonium salt in the cleaning composition ranges from 0.2% to 10% by weight. In the range, the cleaning composition can effectively remove the residues of resists, siloxane resin film layers, or other film layers. If the quaternary ammonium salt accounts for less than 0.2% by weight of the cleaning composition, a hydrolysis reaction of polysiloxane will be too slow, which is not beneficial for the removal of the bottom anti-reflective coatings (BARCs).

### [Water]

In an embodiment of the present disclosure, the cleaning composition of the present disclosure includes water. Preferably, a weight percentage of water ranges from 9% to 35%. If the weight percentage of water is less than 9 wt %, it is not beneficial for the hydrolysis reaction of polysiloxane, while if the weight percentage of water is higher than 35 wt %, it is not beneficial for dissolving the hydrolysis products of the bottom anti-reflective coatings (BARCs). It should be noted that the above weight percentages are proportional ranges of water in a total amount of the cleaning composition.

Specifically, pure water, deionized water, or ultrapure water may be used as water of the present disclosure, which is not specifically limited herein, as long as the weight percentage of water is within the above-mentioned weight ranges.

### [Other Additives]

The cleaning composition for electronics industries of the present disclosure may also include other additives if necessary, such as a surfactant and a metal corrosion inhibitor, under the premise without affecting its cleaning effects on a residue or a residual film on the electronic device components. The cleaning composition for electronics industries of the present disclosure may also include other solvents if necessary under the premise without affecting its cleaning effects on the residue or the residual film on the electronic device components.

Specifically, the metal corrosion inhibitor may be, for example, benzimidazole, benzotriazole, tolyltriazole, 3-amino-1,2,4-triazole, 1,2,4-triazole, 1,2,3-triazole, 5-aminotetrazole, 2,6-pyridinedicarboxylic acid, phenylurea, p-methoxyphenol, pyrocatechol, resorcinol, 2-hydroxypyridine, 2-aminophenol, 8-hydroxyquinoline, phosphoric acid, boric acid, phthalic acid, ascorbic acid, adipic acid, malic acid, oxalic acid, salicylic acid, etc.

The surfactant may be an anionic surfactant, a cationic surfactant, or a non-ionic surfactant, and is not specifically limited herein. The surfactant may be, for example, polyoxyethylene alkyl ether, ethylene oxide/propylene oxide copolymer, polyoxyethylene alkyl aryl ether, acetylenic diol-based surfactants, etc.; specifically, such as octylphenol polyethylene glycol ether, ethoxylated tetramethyldecynediol, etc.

In another embodiment of the present disclosure, the cleaning composition consists of 40% to 90% by weight of the amine solvent having the structure of following formula (1), the quaternary ammonium salt, and water;

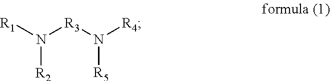

wherein, R₁, R₂, R₄, and R₅ are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R₃ is a linear alkylene group having 1 to 5 carbon atoms or a branched alkylene group having 3 to 5 carbon atoms.

It can be understood that the cleaning composition of the present disclosure can have excellent cleaning effects when even not including other additives, that is, when the composition only includes 40% to 90% by weight of the amine solvent having the structure of formula (1), the quaternary ammonium salt, and water.

### [Cleaning Method]

The cleaning method of the present disclosure includes a step of using the cleaning composition of the present disclosure to clean and remove a residue or a residual film attached onto any device component. The cleaning method of the present disclosure includes various cleaning methods, such as immersion cleaning, spray cleaning, or other cleaning methods. The residue or the residual film mentioned above includes the resists or inorganic substances containing silicon atoms in the siloxane resin film layers. The device component mentioned above is not specifically limited, as long as it is necessary to use film layers such as resist films, anti-reflective films, sacrificial films composed of inorganic films such as silicon masks that contain silicon atoms, or protective films, and then the film layers need to be removed, which all belong to the scope of the device component of the present disclosure. Specifically, the device component may be, for example, a semiconductor device or a semiconductor component.

### [Manufacturing Method of Semiconductor]

The present disclosure also provides a manufacturing method of a semiconductor, which includes following steps:
providing a substrate;
coating a siloxane resin layer on the substrate;
coating a photoresist layer on the siloxane resin layer to form a multilayered substrate;
performing photolithography and etching processes on the multilayered substrate; and
using the cleaning composition of the present disclosure to clean and remove residues of the siloxane resin layer and the photoresist layer attached onto the substrate.

Specifically, the substrate is a semiconductor substrate, such as a silicon substrate. The siloxane resin layer as an anti-reflective coating layer, the photoresist layer is coated on the siloxane resin layer to pattern the siloxane resin layer by the photolithography process, and a pattern is transferred to the substrate by the etching process to complete patterning of the substrate. Next, the cleaning composition of the present disclosure is used to clean and remove the residues of the siloxane resin layer and the photoresist layer attached onto the substrate.

### EXAMPLES

Specific examples 1 to 13 of the present disclosure and comparative examples 1 to 10 are shown in table 1, and evaluation results of removal abilities thereof are shown in table 2.

TABLE 1

| | | | quaternary | | |
|---|---|---|---|---|---|
| | amine | | ammonium salt | | water |
| | | amount | | amount | amount |
| composition | type | (wt %) | type | (wt %) | (wt %) |
| Example 1 | ethylenediamine | 78 | TEAH | 2 | 20 |
| Example 2 | 1,3-diaminopropane | 78 | TEAH | 2 | 20 |
| Example 3 | N,N-dimethyl-1,3- | 78 | TEAH | 2 | 20 |
| | diaminopropane | | | | |
| Example 4 | N,N-diethyl-1,3- | 78 | TEAH | 2 | 20 |
| | diaminopropane | | | | |
| Example 5 | diethylenetriamine | 78 | TEAH | 2 | 20 |
| Example 6 | 1,2-propanediamine | 78 | TEAH | 2 | 20 |
| Example 7 | N,N,N′,N′- | 78 | TEAH | 2 | 20 |
| | tetramethyl- | | | | |
| | 1,3-propanediamine | | | | |
| Example 8 | 3,3′-diamino- | 78 | TEAH | 2 | 20 |
| | dipropylamine | | | | |
| Example 9 | 2,2-dimethyl-1,3- | 78 | TEAH | 2 | 20 |
| | propanediamine | | | | |
| Example 10 | N,N-diethyl-1,3- | 86.4 | TEAH | 0.9 | 12.7 |
| | diaminopropane | | | | |
| Example 11 | N,N-diethyl-1,3- | 90 | TMAH | 0.2 | 9.8 |
| | diaminopropane | | | | |
| Example 12 | N,N-diethyl-1,3- | 86.6 | TMAH | 0.6 | 12.8 |
| | diaminopropane | | | | |
| Example 13 | N,N-diethyl-1,3- | 40 | TEAH | 10 | 12.8 |
| | diaminopropane | | | | |
| Comparative | ethanolamine | 78 | TEAH | 2 | 20 |
| Example 1 | | | | | |
| Comparative | 3-aminopropanol | 78 | TEAH | 2 | 20 |
| Example 2 | | | | | |
| Comparative | isopropanolamine | 78 | TEAH | 2 | 20 |
| Example 3 | | | | | |
| Comparative | N- | 78 | TEAH | 2 | 20 |
| Example 4 | methylethanolamine | | | | |
| Comparative | N-(2-Amino- | 78 | TEAH | 2 | 20 |
| Example 5 | ethyl)ethanolamine | | | | |
| Comparative | 2-amino-2-methyl- | 78 | TEAH | 2 | 20 |
| Example 6 | 1-propanol | | | | |
| Comparative | N,N-diethyl-1,3- | 100 | — | — | — |
| Example 7 | diaminopropane | | | | |
| Comparative | N,N-diethyl-1,3- | 90 | — | — | 10 |
| Example 8 | diaminopropane | | | | |
| Comparative | N,N-diethyl-1,3- | 96 | TEAH | 1 | 3 |
| Example 9 | diaminopropane | | | | |
| Comparative | N,N-diethyl-1,3- | 30 | TEAH | 10 | 60 |
| Example 10 | diaminopropane | | | | |

TABLE 2

| | removal abilities |
|---|---|
| Example 1 | ⊚ |
| Example 2 | ⊚ |
| Example 3 | ⊚ |
| Example 4 | ⊚ |
| Example 5 | ◯ |
| Example 6 | ⊚ |
| Example 7 | ◯ |
| Example 8 | ◯ |
| Example 9 | ◯ |
| Example 10 | ⊚ |
| Example 11 | ⊚ |
| Example 12 | ⊚ |
| Example 13 | ◯ |
| Comparative Example 1 | X |
| Comparative Example 2 | X |
| Comparative Example 3 | X |
| Comparative Example 4 | X |
| Comparative Example 5 | X |
| Comparative Example 6 | X |
| Comparative Example 7 | X |
| Comparative Example 8 | X |
| Comparative Example 9 | X |
| Comparative Example 10 | X |

Evaluation of removal ability: a polysiloxane anti-reflective layer is taken as an example in the present disclosure. ⊚ means that the polysiloxane anti-reflective layer can be removed within 60 seconds, ∘ means that the polysiloxane anti-reflective layer can be removed within 60 to 180 seconds, and X means that the polysiloxane anti-reflective layer cannot be removed within 180 seconds or still has residues.

The polysiloxane anti-reflective layer mentioned above is a cured film layer having a thickness of 120 nm, which is formed by coating a polysiloxane resin onto a silicon wafer and then baking for 3 minutes. Then cured film layers are individually soaked in cleaning compositions of the examples and the comparative examples as cleaning agents for 180 seconds, and temperatures of the cleaning agents are 60° C. After soaking, the cured film layers are rinsed with pure water at 22° C. for 30 seconds. After drying by air blade, confirming a removal state of the cured film layers on surfaces of silicon wafers. The removal state of the cured film layers on the surfaces of the silicon wafers can be judged directly with naked eyes.

From the foregoing examples and comparative examples, it can be seen that compared to Comparative examples 1-6 that do not contain the amine solvent having the structure of formula (1) and Comparative examples 7-10 that do not have the amine solvent having the structure of formula (1) ranging from 40% to 90% by weight, the cleaning composition of the present disclosure has excellent cleaning effects since it includes 40% to 90% by weight of the amine solvent having the structure of formula (1), the quaternary ammonium salt, and water. In addition, from Examples 1 to 9, it can be known that when R₁ and R₂ of the amine solvent having the structure of formula (1) are each independently hydrogen or a linear alkyl group having 1 to 2 carbon atoms, R₄ and R₅ are hydrogen, and R₃ is a linear alkylene group having 1 to 3 carbon atoms, the cleaning composition of the present disclosure may even remove the polysiloxane cured film layer on the surface of the silicon wafer within 30 seconds.

The composition of the cleaning composition of the present disclosure is simple, so the preparation cost can be saved. Moreover, the cleaning composition of the present disclosure can effectively remove the residues of resists, siloxane resin film layers, or other film layers under the premise of taking environmental protection into consideration, therefore, has excellent cleaning effects.

Although the present disclosure has been disclosed in a number of preferred embodiments, it is not intended to limit the present disclosure, but only to enable those with ordinary knowledge to clearly understand the implementation content of the present disclosure. For a person of ordinary skill in the art, various changes and modifications can be made without departing from the spirit and scope of the present disclosure that is intended to be limited only by the appended claims.

What is claimed is:

1. A cleaning composition for electronics industries, comprising 40% to 90% by weight of an amine solvent having a structure of following formula (1), a quaternary ammonium salt, and water; 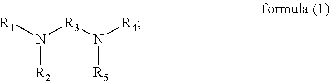
wherein, R₁, R₂, R₄, and R₅ are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R₃ is a linear alkylene group having 1 to 5 carbon atoms or a branched alkylene group having 3 to 5 carbon atoms.

2. The cleaning composition according to claim 1, wherein R₁ and R₂ are each independently hydrogen or the linear alkyl group having 1 to 4 carbon atoms; R₄ and R₅ are each independently hydrogen, a linear alkyl group having 1 to 2 carbon atoms, or a linear alkylamine having 1 to 2 carbon atoms; and R₃ is the linear alkylene group having 1 to 5 carbon atoms or the branched alkylene group having 3 to 5 carbon atoms.

3. The cleaning composition according to claim 1, wherein R₁ and R₂ are each independently hydrogen or a linear alkyl group having 1 to 3 carbon atoms; R₄ and R₅ are each independently hydrogen; and R₃ is a linear alkylene group having 1 to 4 carbon atoms or the branched alkylene group having 3 to 5 carbon atoms.

4. The cleaning composition according to claim 1, wherein the amine solvent comprises N,N-dimethyl-1,3-diaminopropane, N,N-diethyl-1,3-diaminopropane, ethylenediamine, 1,3-diaminopropane, diethylenetriamine, 1,2-propanediamine, N,N,N′,N′-tetramethyl-1,3-propanediamine, 3,3′-diaminodipropylamine, 2,2-dimethyl-1,3-propanediamine, 1,4-diaminobutane, 1,3-diaminobutane, 2,3-diaminobutane, 1,5-diaminopentane, or 2,4-diaminopentane.

5. The cleaning composition according to claim 1, wherein the quaternary ammonium salt is quaternary ammonium hydroxide having a structure shown in a following formula (2): 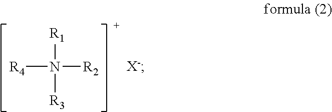
wherein, R₁ to R₄ are each independently an alkyl group having 1 to 4 carbon atoms that is unsubstituted or substituted with a hydroxyl group, and X is OH.

6. The cleaning composition according to claim 2, wherein the quaternary ammonium salt is quaternary ammonium hydroxide having a structure shown in a following formula (2): 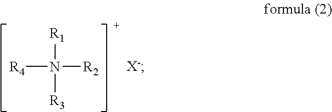
wherein, R₁ to R₄ are each independently an alkyl group having 1 to 4 carbon atoms that is unsubstituted or substituted with a hydroxyl group, and X is OH.

7. The cleaning composition according to claim 4, wherein the quaternary ammonium salt is quaternary ammonium hydroxide having a structure shown in a following formula (2): 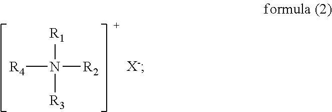
wherein, R₁ to R₄ are each independently an alkyl group having 1 to 4 carbon atoms that is unsubstituted or substituted with a hydroxyl group, and X is OH.

8. The cleaning composition according to claim 1, wherein an amount of the quaternary ammonium salt in the cleaning composition ranges from 0.2% to 10% by weight.

9. The cleaning composition according to claim 1, wherein an amount of the amine solvent in the cleaning composition ranges from 65% to 90% by weight, and an amount of water in the cleaning composition ranges from 9% to 35% by weight.

10. A cleaning composition for electronics industries, consisting of 40% to 90% by weight of an amine solvent having a structure of following formula (1), a quaternary ammonium salt, and water; 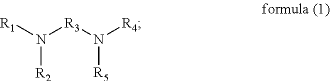
wherein, R₁, R₂, R₄, and R₅ are each independently hydrogen, a linear alkyl group having 1 to 4 carbon atoms, a branched alkyl group having 3 to 5 carbon atoms, a linear alkylamine having 1 to 4 carbon atoms, or a branched alkylamine having 3 to 5 carbon atoms, and R₃ is a linear alkylene group having 1 to 5 carbon atoms or a branched alkylene group having 3 to 5 carbon atoms.

11. A cleaning method, comprising a step of using the cleaning composition according to claim 1 to clean and remove a residue or a residual film attached onto a device component, wherein the residue or the residual film comprises a resist or a siloxane resin film layer.

12. A manufacturing method of a semiconductor, comprising following steps:
providing a substrate;
coating a siloxane resin layer on the substrate;
coating a photoresist layer on the siloxane resin layer to form a multilayered substrate;
performing photolithography and etching processes on the multilayered substrate; and
using the cleaning composition according to claim 1 to clean and remove residues of the siloxane resin layer and the photoresist layer attached onto the substrate.
